(19) United States
(12) Patent Application Publication
(10) Pub. No.: US 2024/0084481 A1
(43) Pub. Date: Mar. 14, 2024

(54) FABRICATION TECHNIQUE FOR HYDROGEL FILMS CONTAINING MICROPATTERNED OPAL STRUCTURES

(71) Applicant: Trustees of Tufts College, Medford, MA (US)

(72) Inventors: Hyunmin YI, Lexington, MA (US); Maurice Bukenya, Medford, MA (US); Subhash Kalidindi, Arlington, MA (US)

(21) Appl. No.: 18/271,135

(22) PCT Filed: Jan. 10, 2022
(86) PCT No.: PCT/US22/11812

§ 371 Date: Jul. 6, 2023

Related U.S. Application Data
(60) Provisional application No. 63/135,245, filed on Jan. 8, 2021.

(51) Int. Cl. C30B 29/58; B82Y 20/00; B82Y 30/00; C30B 5/00

(52) U.S. Cl. CPC C30B 29/58; B82Y 20/00; B82Y 30/00; C30B 5/00

(57) ABSTRACT

Disclosed is a method for producing a micropatterned opal hydrogel film comprising an evaporation-polymerization method. The method provides a simple and inexpensive fabrication method to produce micropatterned opal hydrogel films.

### RELATED APPLICATION

This application claims the benefit of priority to U.S. Provisional Patent Application No. 63/135,245, filed Jan. 8, 2021.

### GOVERNMENT SUPPORT

This invention was made with government support under Grant Number 1703549, awarded by the National Science Foundation. The government has certain rights in the invention.

### BACKGROUND

Naturally occurring opal gemstones exhibit brilliant opalescent color arising from the diffraction of visible light by regularly ordered spherical particles of amorphous silica in the 150 to 400 nm size range (1-4). Such optically active properties can be readily mimicked by controlled assembly of nanoparticles to create artificial opals. Because of the structural colors that can be readily controlled by the particle size, artificial opals have gained significant attention for optical applications. Hydrogel materials containing such opal structures can provide a dynamic optical response to environmental variables such as humidity, pH, and ionic strength (5-11) in the readily recognizable visible color range and thus have emerged as promising materials for sensing.

Micropatterned hydrogels have been used for creating microenvironments to manipulate and allow controlled growth of cells (12). Furthermore, micropatterned opal hydrogel materials can offer various advantages including ready addressability, high throughput assaying, and multiplexing capability for a range of applications including protein patterning (13), enzyme detection (14), and high-sensitivity humidity sensing (15). Despite such potential, existing fabrication technologies for micropatterned opal hydrogel materials face limitations. While widely available and mature, typical photolithography-based techniques suffer from extensive equipment needs, arduous multistep procedures, and long processing time (13, 15-18). In contrast, soft-lithographic techniques offer simpler routes to the fabrication of micropatterned opal hydrogel materials (19-21). For example, imprinting lithography (22, 23) and templating methods (19, 20, 24, 25) have been utilized to generate micropatterned opal and inverse opal structures; however, these methods often involve exquisitely controlled equipment or rely on external forces (e.g., capillary microfluidics) to drive the patterning or assembly (16, 18, 24). Thus, there exists a critical need for a simple, rapid, and readily controllable fabrication approach for micropatterned opal hydrogel films.

### SUMMARY OF INVENTION

The present invention provides a method for producing a micropatterned opal hydrogel film, comprising:
(i) depositing a suspension of nanoparticles in at least one solvent into a plurality of poly(dimethylsiloxane) (PDMS) microwells;
(ii) subjecting the suspension, for a first period of time, to conditions sufficient to evaporate the at least one solvent;
(iii) adding a prepolymer solution comprising a monomer and/or a co-monomer to the plurality of PDMS microwells; and
(iv) subjecting the prepolymer solution, for a second period of time to conditions sufficient to polymerize the monomer and/or co-monomer, thereby producing the micropatterned opal hydrogel film.

Another aspect of the present invention provides a method for producing a micropatterned opal hydrogel film, comprising:
(i) depositing a suspension of polystyrene (PS) beads in at least one solvent into a plurality of poly(dimethylsiloxane) (PDMS) microwells;
(ii) subjecting the plurality of PDMS microwells, for a first period of time, to conditions sufficient to evaporate the at least one solvent;
(iii) adding a prepolymer solution comprising a monomer and/or a co-monomer and a photoinitiator to the plurality of PDMS microwells; and
(iv) exposing the solution to UV light for a second period of time to polymerize the monomer and/or co-monomer, thereby producing the micropatterned opal hydrogel film.

### BRIEF DESCRIPTION OF THE DRAWINGS

FIG. 1A: Evaporation-polymerization approach for micropatterned opal hydrogel films. Schematic diagram of the fabrication process.

FIG. 1B: Photograph (purple) of micropatterned poly(dimethylsiloxane) (PDMS) mold with circular microwells upon deposition of polystyrene (PS) beads.

FIG. 1C: Photograph of a micropatterned opal hydrogel film (green).
FIG. 2A: Evaporative deposition of PS beads into opal structured micropatterns. Dark-field optical micrographs and the corresponding UV-vis reflectance spectra of micropatterns from deposition of PS beads of diameter 182 nm (PS182) in circle-shaped microwells. Photographs of the micropatterns in PDMS mold showing faint purple color. Yellow scale bars represent 200 μm.

FIG. 2B: Evaporative deposition of PS beads into opal structured micropatterns. Dark-field optical micrographs and the corresponding UV-vis reflectance spectra of micropatterns from deposition of PS beads of diameter 190 nm (PS190) in circle-shaped microwells. Photographs of the micropatterns in PDMS molds showing purple color. Yellow scale bars represent 200 μm.

FIG. 2C: Evaporative deposition of PS beads into opal structured micropatterns. Dark-field optical micrographs and the corresponding UV-vis reflectance spectra of micropatterns from deposition of PS beads of diameter 204 nm (PS204) in circle-shaped microwells. Photographs of the micropatterns in PDMS molds showing teal color. Yellow scale bars represent 200 μm.

FIG. 2D: Evaporative deposition of PS beads into opal structured micropatterns. Dark-field optical micrographs and the corresponding UV-vis reflectance spectra of micropatterns from deposition of PS beads of diameter 264 nm (PS264) in circle-shaped microwells. Insets: Photographs of the micropatterns in PDMS molds showing red color. Yellow scale bars represent 200 μm.

FIG. 2E: Table showing the PS bead sizes measured by DLS.

FIG. 3A: Effects of PEGDA content on opal color. Dark-field images of four different films prepared with PS182 beads and varying PEGDA content (10-60% (v/v)). Green to purple color (left to right).

FIG. 3B: Effects of PEGDA content on opal color. Films prepared with PS190 beads. All images were taken in DI water. Green to blue color (left to right). Yellow scale bars represent 200 μm.

FIG. 3C: Effects of PEGDA content on opal color. Films prepared with PS204. All images were taken in DI water. Orange to green color (left to right). Yellow scale bars represent 200 μm.

FIG. 4A: SEM images of the micropatterned opal-containing PEG hydrogel film. Top view of the film showing representative micropatterns.

FIG. 4B: SEM images of the micropatterned opal-containing PEG hydrogel film. Tilted view of the film showing the sides of micropatterns.

FIG. 4C: SEM images of the micropatterned opal-containing PEG hydrogel film. Close-up view of an individual micropattern showing an opal-containing layer on the top and the hydrogel layer beneath it.

FIG. 4D: SEM images of the micropatterned opal-containing PEG hydrogel film. Image of the opal layer showing the FCC arrangement of PS beads. Inset: Enlarged portion of the FCC structure.

FIG. 5A: Responsiveness of micropatterned opal hydrogel films to water content. Optical micrographs showing change in color of a PS204 10% PEGDA film in wet vs dried states. Red to green color (left to right).

FIG. 5B: Normalized UV-vis reflectance spectra of the wet and dried states of the film FIG. 5A.

FIG. 5C: Normalized UV-vis reflectance spectra of films fabricated with PS182 and 10 and 60% PEGDA, respectively. Δλₘₐₓ indicates the change in the maximum wavelength upon drying.

FIG. 5D: SEM images of films fabricated with PS204 and 10 and 60% PEGDA, respectively, upon 30 min of drying at room temperature. The insets show tilted zoomed-in view of each state.

FIG. 6A: Responsiveness of carboxylate-containing micropatterned opal hydrogel films to pH. Dark-field optical micrographs of a square-shaped micropatterned poly-(hydroxyethylmethacrylate-co-acrylic acid-co-methacrylic acid) (poly(HEMA-co-AA-co-MAA)) film made with PS204 immersed in pH 2.92. Film is green colored.

FIG. 6B: Responsiveness of carboxylate-containing micropatterned opal hydrogel films to pH. Dark-field optical micrographs of a square-shaped micropatterned poly(HEMA-co-AA-co-MAA) film made with PS204 immersed in pH 6.4. Film is yellow-green colored.

FIG. 6C: Responsiveness of carboxylate-containing micropatterned opal hydrogel films to pH. Dark-field optical micrographs of a square-shaped micropatterned poly(HEMA-co-AA-co-MAA) film made with PS204 immersed in pH 7.0. Film is yellow-green colored.

FIG. 6D: Responsiveness of carboxylate-containing micropatterned opal hydrogel films to pH. Dark-field optical micrographs of a square-shaped micropatterned poly(HEMA-co-AA-co-MAA) film made with PS204 immersed in pH 7.6. Film is orange colored.

FIG. 6E: Extended SEM views of the square-shaped micropatterns.
FIG. 6F: Zoomed-in SEM views of the square-shaped micropatterns.
FIG. 7: Reversibility in the responsiveness of micropatterned opal hydrogel films to change in water content. PS204 — 10% PEGDA film exhibiting uniform orange color in wet state (top row) and green color in dry state (bottom row) for five drying-wetting cycles. All yellow scale bars represent 200 μm.

FIG. 8: Final PEG polymer content in opal hydrogel films. The data points for PEG and water content are indicated in the blue diamonds and orange circles respectively.

FIG. 9: Peak Wavelengths identified via Image Analysis of the Darkfield Micrographs of the Micropatterned Opal Hydrogel Films in response to pH in FIGS. 6A-D using ImageJ.

FIG. 10: Reversibility in the responsiveness of micropatterned opal hydrogel films to change in pH. The opal hydrogel films were fabricated with PS204 and prepolymer solution containing 15% (v/v) HEMA, 7% (v/v) PEGDA, 10% (v/v) AA, and 10% (v/v) MAA. All yellow scale bars represent 200 μm. Orange color in top row and green color in bottom row.

### DETAILED DESCRIPTION OF THE INVENTION

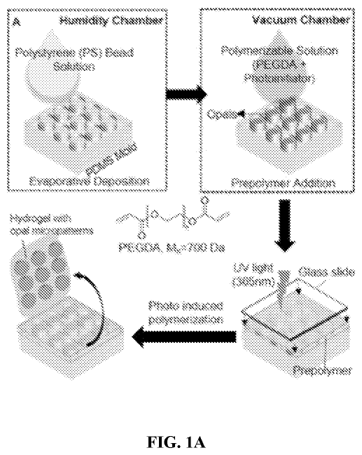

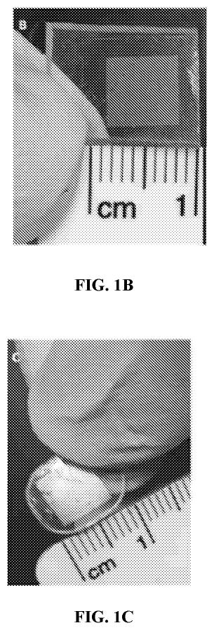

The present invention relates to a simple micromolding-based evaporation-polymerization method for deposition of micropatterned opal structures and their integration into hydrogels, as shown in the schematic diagram of FIG. 1A. Micromolding, a soft-lithographic technique that enables simple and inexpensive replication and transfer of patterns, provides efficient physical confinement of nanoparticles during opal formation and prepolymer infiltration.

Aqueous suspensions of monodisperse PS beads with size ranges in the nanometer scale are filled into patterned microwells on PDMS molds. Upon removing excess solution by pipetting, simple evaporation leads to rapid and spontaneous assembly of the PS beads into regularly ordered face-centered cubic (FCC) structures, yielding micropatterned opal structures showing brilliant color (FIG. 1B). Next, the opal micropatterns are covered with a photocurable prepolymer solution, which is polymerized by exposure to UV light (365 nm) with a simple handheld UV lamp to create hydrogel films that capture the opal micropatterns (FIG. 1C).

The results indicate reliable fabrication of opal micropatterns with a precise assembly structure and color via simple evaporative deposition. Next, photopolymerization leads to hydrogel films with uniform and intense color that can be controlled simply by tuning the prepolymer solution compositions. Scanning electron microscopy (SEM) images confirm closely packed structural arrangement of the PS beads and reveal uniform film micropatterns, indicating efficient packing and polymerization. SEM and dynamic light scattering (DLS) separately give bead sizes in close agreement with the theoretical sizes estimated by the modified Bragg equation. Drying and wetting experiments illustrate significant and reversible shift in colors, showing the versatile nature of the hydrogel film format.

Hydrogel films prepared with carboxylate functionalities provide a reliable response to pH, showing potential for sensing applications. Combined, these results indicate a facile fabrication technique for potent functional hydrogel materials containing micropatterned opal structures. The fabrication technique disclosed herein can be readily extended to manufacture a variety of functional materials for many applications in a simple and low-cost manner.

### Definitions

The term “micropatterned opal hydrogel film” as used herein refers to an opal hydrogel film having a topography including a micropattern defined by a plurality of spaced features. For example, the spaced features may include, but are not limited to circle or square shaped spaced features projecting from the surface of the film. Said spaced features result from the shape of the microwell employed in the disclosed method.

The term “monomer” as used herein refers to refer to a starting unit for a polymer. A monomer is a single molecule that can react with other monomers to form a polymer. In the process of the present invention, monomers include, but are not limited to, poly(ethylene glycol), poly(ethylene glycol) diacrylate, 2-hydroxyethylmethacrylate, elatin, agarose, chitosan, ionogel (choline chloride:propanediol), poly(ethylene glycol) dimethacrylate, acrylamide, or alginate.

The term “co-monomer” as used herein refers to a polymerizable precursor to a copolymer aside from the principal monomer. In the process of the present invention, co-monomers include, but are not limited to, chitosan, acrylic acid, methacrylic acid, gelatin, or bisacrylamide.

### Exemplary Embodiments of the Invention

The present invention provides a method for producing a micropatterned opal hydrogel film, comprising:
(i) depositing a suspension of nanoparticles in at least one solvent into a plurality of poly(dimethylsiloxane) (PDMS) microwells;
(ii) subjecting the suspension, for a first period of time, to conditions sufficient to evaporate the at least one solvent;
(iii) adding a prepolymer solution comprising a monomer and/or a co-monomer to the plurality of PDMS microwells; and
(iv) subjecting the prepolymer solution, for a second period of time to conditions sufficient to polymerize the monomer and/or co-monomer, thereby producing the micropatterned opal hydrogel film.

In certain embodiments, the plurality of PDMS microwells are circle shaped.

In certain embodiments, the micropatterned opal hydrogel film is characterized by a plurality of circle shaped surface features.

In certain embodiments, each circle shaped surface feature has a uniform diameter ±5 μm.

In certain embodiments, each circle shaped surface feature is spaced apart by a uniform distance ±2 μm.

In certain embodiments, the plurality of PDMS microwells are square shaped. In certain embodiments, the micropatterned opal hydrogel film is characterized by a plurality of square shaped surface features

In certain embodiments, each square shaped surface feature has a uniform width ±5 μm.

In certain embodiments, each square shaped surface feature is spaced apart by a uniform distance ±2 μm.

In certain embodiments, the PS beads are suspended in a mixture comprising water and an organic solvent.

In certain embodiments, the PS beads are suspended in a 5:5 to 7:3 mixture of water and an organic solvent.

In certain embodiments, the PS beads are suspended in a 6:4 mixture of water and an organic solvent.

In certain embodiments, the organic solvent is an alcohol. In certain embodiments, the alcohol is ethanol.

In certain embodiments, the nanoparticles are polystyrene (PS) beads.

In certain embodiments, the PS beads have a diameter of about 180-219 nm. In other embodiments, the PS beads have a diameter of about 260-279 nm.

In certain embodiments, the PS beads have a diameter of about 180-189 nm. In other embodiments, the PS beads have a diameter of about 190-199 nm. In other embodiments, the PS beads have a diameter of about 200-209 nm. In other embodiments, the PS beads have a diameter of about 210-219 nm. In other embodiments, the PS beads have a diameter of about 260-269 nm. In other embodiments, the PS beads have a diameter of about 270-279 nm.

In certain embodiments, the nanoparticles are silica nanoparticles.

In certain embodiments, in step (ii) the suspensions are subjected a relative humidity of 80-99%. In other embodiments, the relative humidity of 85-95%. In other embodiments, the relative humidity of 88-92%.

In certain embodiments, the first period of time is about 15 to 45 min. In other embodiments, the first period of time is about 30 min.

In certain embodiments, in step (iii) the monomer or co-monomer is about 5-65% v/v in the prepolymer solution. In certain embodiments, the monomer or co-monomer is about 5-15% v/v in the prepolymer solution. In other embodiments, the monomer or co-monomer is about 15-25% v/v in the prepolymer solution. In other embodiments, the monomer or co-monomer is about 35-45% v/v in the prepolymer solution. In other embodiments, the monomer or co-monomer is about 55-65% v/v in the prepolymer solution.

In certain embodiments, the solution is an aqueous solution.
In certain embodiments, in step (iii) the prepolymer solution comprises a monomer that is polymerizable by UV radiation.

In certain embodiments, in step (iii) the prepolymer solution comprises a co-monomer that is polymerizable by UV radiation.

In certain embodiments, the monomer is a polyether acrylate monomer or a methacrylate monomer.

In certain embodiments, the monomer is polyethylene glycol diacrylate (PEGDA).
In certain embodiments, the monomer is 2-hydroxyethylmethacrylate (HEMA).
In certain embodiments, the monomer is poly(ethylene glycol), dimethacrylate, or acrylamide.

In certain embodiments, the co-monomer is acrylic acid, methacrylic acid, or bisacrylamide.

In certain embodiments, in step (iv) the monomer or co-monomer is subjected to UV light to polymerize the monomer or co-monomer.

In certain embodiments, the UV light is 365 nm UV light.
In certain embodiments, the second period of time is about 15 to about 45 min.
In certain embodiments, the second period of time is about 30 min.

In certain embodiments, the prepolymer solution is to vacuum for about 15 to about 45 min prior to being subject to UV light.

In certain embodiments, in step (iii) the prepolymer solution comprises a monomer which is polymerizable by thermal polymerization.

In certain embodiments, in step (iii) the prepolymer solution comprises a co-monomer which is polymerizable by thermal polymerization.

In certain embodiments, the thermal polymerization is thermal gelation.
In certain embodiments, the monomer is gelatin, agarose, or ionogel
In certain embodiments, the co-monomer is gelatin.
In certain embodiments, the prepolymer solution is a hot solution.
In certain embodiments, the prepolymer solution is heated to boiling prior to addition to the plurality of PDMS microwells.

In certain embodiments, in step (iv) the hot prepolymer solution of the monomer or co-monomer is allowed to cool to room temperature to polymerize the monomer or co-monomer.

In certain embodiments, the in step (iii) the prepolymer solution comprises a monomer which is polymerizable by exposure to a Ca²⁺.

In certain embodiments, the in step (iii) the prepolymer solution comprises a co-monomer which is polymerizable by exposure to a Ca²⁺.

In certain embodiments, the monomer is alginate
In certain embodiments, the in step (iv) a solution comprising Ca²⁺ is added to the plurality of PDMS microwells to polymerize the monomer or co-monomer.

In certain embodiments, in step (iii) the prepolymer solution comprises a monomer, which is polymerizable by exposure to a strong base.

In certain embodiments, in step (iii) the prepolymer solution comprises a co-monomer, which is polymerizable by exposure to strong base.

In certain embodiments, the monomer is chitosan.
In certain embodiments, the co-monomer is chitosan.
In certain embodiments, in step (iv) a strongly basic solution is added to the plurality of PDMS microwells to polymerize the monomer or co-monomer. Another aspect of the present invention provides a method for producing a micropatterned opal hydrogel film, comprising:
(i) depositing a suspension of polystyrene (PS) beads in at least one solvent into a plurality of poly(dimethylsiloxane) (PDMS) microwells;
(ii) subjecting the suspension, for a first period of time, to conditions sufficient to evaporate the at least one solvent;
(iii) adding a prepolymer solution comprising a monomer and/or a co-monomer and a photoinitiator to the plurality of PDMS microwells; and
(iv) exposing the prepolymer solution to UV light for a second period of time to polymerize the monomer and/or co-monomer, thereby producing the micropatterned opal hydrogel film.

In certain embodiment, step (iii) further comprises subjecting the plurality of PDMS microwells to vacuum for a third period of time. In certain embodiments, the third period of time is about 15 to 45 min. In other embodiments, the third period of time is about 30 min.

In certain embodiments, the plurality of PDMS microwells are circle shaped.

In certain embodiments, the micropatterned opal hydrogel film is characterized by a plurality of circle shaped surface features.

In certain embodiments, each circle shaped surface feature has a uniform diameter ±5 μm.

In certain embodiments, each circle shaped surface feature is spaced apart by a uniform distance ±2 μm.

In certain embodiments, the plurality of PDMS microwells are square shaped.

In certain embodiments, the micropatterned opal hydrogel film is characterized by a plurality of square shaped surface features

In certain embodiments, each square shaped surface feature has a uniform width ±5 μm.

In certain embodiments, each square shaped surface feature is spaced apart by a uniform distance ±2 μm.

In certain embodiments, the PS beads are suspended in a mixture comprising water and an organic solvent.

In certain embodiments, the PS beads are suspended in a 5:5 to 7:3 mixture of water and an organic solvent.

In certain embodiments, the PS beads are suspended in a 6:4 mixture of water and an organic solvent.

In certain embodiments, the organic solvent is an alcohol. In certain embodiments, the alcohol is ethanol.

In certain embodiments, the PS beads have a diameter of about 180-219 nm. In other embodiments, the PS beads have a diameter of about 260-279 nm.

In certain embodiments, the PS beads have a diameter of about 180-189 nm. In other embodiments, the PS beads have a diameter of about 190-199 nm. In other embodiments, the PS beads have a diameter of about 200-209 nm. In other embodiments, the PS beads have a diameter of about 210-219 nm. In other embodiments, the PS beads have a diameter of about 260-269 nm. In other embodiments, the PS beads have a diameter of about 270-279 nm.

In certain embodiments, in step (ii) the suspensions are subjected a relative humidity of 80-99%. In other embodiments, the relative humidity of 85-95%. In other embodiments, the relative humidity of 88-92%.

In certain embodiments, the first period of time is about 15 to 45 min. In other embodiments, the first period of time is about 30 min.

In certain embodiments, in step (iii) the monomer or co-monomer is about 5-65% v/v in the prepolymer solution. In certain embodiments, the monomer or co-monomer is about 5-15% v/v in the prepolymer solution. In other embodiments, the monomer or co-monomer is about 15-25% v/v in the prepolymer solution. In other embodiments, the monomer or co-monomer is about 35-45% v/v in the prepolymer solution. In other embodiments, the monomer or co-monomer is about 55-65% v/v in the prepolymer solution.

In certain embodiments, the prepolymer solution is an aqueous solution.

In certain embodiments, the monomer is a polyether acrylate monomer or a methacrylate monomer.

In certain embodiments, the monomer is polyethylene glycol diacrylate (PEGDA). In other embodiments, the monomer is hydroxyethylmethacrylate (HEMA).

In certain embodiments, the second period of time is about 15 to 45 min. In other embodiments, the second period of time is about 30 min.

In certain embodiments, in step (iv) the UV light is 365 nm UV light.

In certain embodiments, the second period of time is about 15 to 45 min. In other embodiments, the second period of time is about 30 min.

In certain embodiments, the PS beads have a diameter of about 180-189 nm; and the monomer or co-monomer is about 5-15% v/v in the prepolymer solution. In other embodiments, the PS beads have a diameter of about 180-189 nm; and the monomer or co-monomer is about 15-25% v/v in the prepolymer solution. In other embodiments, the PS beads have a diameter of about 180-189 nm; and the monomer or co-monomer is about 35-45% v/v in the prepolymer solution. In other embodiments, the PS beads have a diameter of about 180-189 nm; and the monomer or co-monomer is about 55-65% v/v in the prepolymer solution.

In certain embodiments, the PS beads have a diameter of about 190-199 nm; and the monomer or co-monomer is about 5-15% v/v in the prepolymer solution. In other embodiments, the PS beads have a diameter of about 190-199 nm; and the monomer or co-monomer is about 15-25% v/v in the prepolymer solution. In other embodiments, the PS beads have a diameter of about 190-199 nm; and the monomer or co-monomer is about 35-45% v/v in the prepolymer solution. In other embodiments, the PS beads have a diameter of about 190-199 nm; and the monomer or co-monomer is about 55-65% v/v in the prepolymer solution.

In certain embodiments, the PS beads have a diameter of about 200-209 nm; and the monomer or co-monomer is about 5-15% v/v in the prepolymer solution. In other embodiments, the PS beads have a diameter of about 200-209 nm; and the monomer or co-monomer is about 15-25% v/v in the prepolymer solution. In other embodiments, the PS beads have a diameter of about 200-209 nm; and the monomer or co-monomer is about 35-45% v/v in the prepolymer solution. In other embodiments, the PS beads have a diameter of about 200-209 nm; and the monomer or co-monomer is about 55-65% v/v in the prepolymer solution.

In certain embodiments, the PS beads have a diameter of about 210-219 nm; and the monomer or co-monomer is about 5-15% v/v in the prepolymer solution. In other embodiments, the PS beads have a diameter of about 210-219 nm; and the monomer or co-monomer is about 15-25% v/v in the prepolymer solution. In other embodiments, the PS beads have a diameter of about 210-219 nm; and the monomer or co-monomer is about 35-45% v/v in the prepolymer solution. In other embodiments, the PS beads have a diameter of about 210-219 nm; and the monomer or co-monomer is about 55-65% v/v in the prepolymer solution.

In certain embodiments, the PS beads have a diameter of about 260-269 nm; and the monomer or co-monomer is about 5-15% v/v in the prepolymer solution. In other embodiments, the PS beads have a diameter of about 260-269 nm; and the monomer or co-monomer is about 15-25% v/v in the prepolymer solution. In other embodiments, the PS beads have a diameter of about 260-269 nm; and the monomer or co-monomer is about 35-45% v/v in the prepolymer solution. In other embodiments, the PS beads have a diameter of about 260-269 nm; and the monomer or co-monomer is about 55-65% v/v in the prepolymer solution.

In certain embodiments, the PS beads have a diameter of about 270-279 nm; and the monomer or co-monomer is about 5-15% v/v in the prepolymer solution. In other embodiments, the PS beads have a diameter of about 270-279 nm; and the monomer or co-monomer is about 15-25% v/v in the prepolymer solution. In other embodiments, the PS beads have a diameter of about 270-279 nm; and the monomer or co-monomer is about 35-45% v/v in the prepolymer solution. In other embodiments, the PS beads have a diameter of about 270-279 nm; and the monomer or co-monomer is about 55-65% v/v in the prepolymer solution.

In certain embodiments, the prepolymer solution further comprises a cross-linker.

In certain embodiments, the opal hydrogel film is a two-layered structure.

In certain embodiments, a first layer is an opal-containing layer and a second layer is a hydrogel layer.

In certain embodiments, a top layer is an opal-containing layer and a bottom layer is a hydrogel layer.

In certain embodiments, the micropatterned opal hydrogel film is green. In other embodiments, the micropatterned opal hydrogel film is yellow. In other embodiments, the micropatterned opal hydrogel film is purple. In other embodiments, the micropatterned opal hydrogel film is blue.

In certain embodiments, the micropatterned opal hydrogel film changes color in response to a change in pH.

The invention also provides a micropatterned opal hydrogel film prepared by the method of the present invention.

The invention also provides a micropatterned opal hydrogel film characterized by a plurality of shaped surface features, wherein each shaped surface features comprises an opal-containing top layer and a hydrogel bottom layer.

The invention also provides a micropatterned opal hydrogel film characterized by a plurality of shaped surface features, wherein each shaped surface features consists of an opal-containing top layer and a hydrogel bottom layer.

In certain embodiments, the shaped surface features are circle or square shaped surface features.

In certain embodiments, each circle shaped surface feature has a uniform diameter ±5 μm.

In certain embodiments, each circle shaped surface feature is spaced apart by a uniform distance ±2μm.

In certain embodiments, each square shaped surface feature has a uniform width ±5 μm.

In certain embodiments, each square shaped surface feature is spaced apart by a uniform distance ±2μm.

In certain embodiments, the opal-containing top layer comprises nanoparticles.

In certain embodiments, the nanoparticles are polystyrene or silica nanoparticles.

In certain embodiments, the opal-containing top layer is formed by evaporating a suspension of the nanoparticles in at least one solvent.

In certain embodiments, the hydrogel bottom layer comprises a polymer.

In certain embodiments, the polymer is formed by polymerization of a monomer and/or co-monomer.

In certain embodiments, the micropatterned opal hydrogel film changes color in response to a change in pH.

### Materials and Methods

Materials. Styrene (Reagent Plus, ≥99% 4-ter-butylcatechol as the stabilizer), polyvinylpyrrolidone (PVP40, Ave. MW 40 kDa), potassium persulfate (KPS, Initiator, 99.99%), poly(ethylene glycol) diacrylate (PEGDA, Mn 700 Da), 2-hydroxy-2-methylpropiophenone (Darocur 1173, photoinitiator (PI)), acrylic acid (AA), methacrylic acid (MAA), 2-hydroxyethylmethacrylate (HEMA), and ethanol were purchased from Sigma-Aldrich (St. Louis, MO). Tween 20 (TW20) was purchased from Thermo Fisher Scientific (Waltham, MA). A poly(dimethylsiloxane) elastomer kit (PDMS, Sylgard 184) was supplied by Dow Corning (Auburn, MI).

PS Bead Synthesis. Monodisperse PS nanospheres (beads) were synthesized using the emulsion polymerization technique (32), from aqueous mixtures of styrene, PVP, and KPS. First, 0.2-0.7 g of PVP was dissolved in 90-100 mL of deionized (DI) water. Following dissolution of PVP, 11 mL of styrene monomer was added into a 250 mL two-neck round bottom (RB) flask. The solution was stirred for 15 min at room temperature. Initiator solution containing 0.15 g of KPS dissolved in 10 mL DI water was added to the RB flask. The mixture was set on a magnetic stirrer and stirred at a rate of 450 rpm, and its temperature was maintained at 72-74° C. The reaction was allowed to run for 24 h, after which the mixture was cooled, washed with DI water, and centrifuged (15,000 rcf and 90 min) three times to remove excess unreacted monomers. The PS bead mixture was then sonicated to remove aggregates.

Micropatterned PDMS Molds. Silicon mastermolds with circular or square patterns fabricated via photolithography were prepared with standard protocols (28-30) and supplied by Professor Chang-Soo Lee's group at Chungnam National University. To fabricate the PDMS molds, the PDMS elastomer was mixed with a curing agent in a 10:1 ratio, and the mixture was poured onto a silicon mastermold and cured at 65° C. The cross-linked PDMS was then peeled off from the silicon mastermold. Molds had a micropatterned area of 0.7×0.7 cm² containing 1600 100 μm×100 μm×46 μm circular or square patterns.

Deposition of PS Beads into Opal Structures. As shown in the schematic diagram of FIG. 1A, 100 μL aqueous suspensions of PS beads containing 40% ethanol and 0.1% TW20 were applied onto the patterned surfaces of the micromolds and filled into the microwells by rubbing through the suspensions with a pipette tip. After removing excess suspension by simple pipetting, the PDMS molds were left in a humidity chamber (relative humidity >90%) for 30 min to allow for controlled evaporation.

Fabrication of Micropatterned Opal Hydrogel Films. The second step of the scheme in FIG. 1A shows the procedure for synthesis of opal hydrogel films via photoinduced radical polymerization using PEGDA as a representative monomer. To synthesize an opal film, aqueous prepolymer solution containing a monomer or co-monomers and 1% (v/v) PI was added onto a PDMS mold containing deposited opal structures. The solution was forced to seep into the microwells and fill the voids of opals in a vacuum chamber for 30 min. Upon covering the micropatterned area with a microscope coverslip, the mold was exposed to UV light (365 nm) using a handheld UV lamp (8 W, Spectronics Corporation, Westbury, NY) for 30 min. Upon polymerization, the opal hydrogel films were recovered by carefully peeling them off the PDMS mold, washed, and stored in DI water.

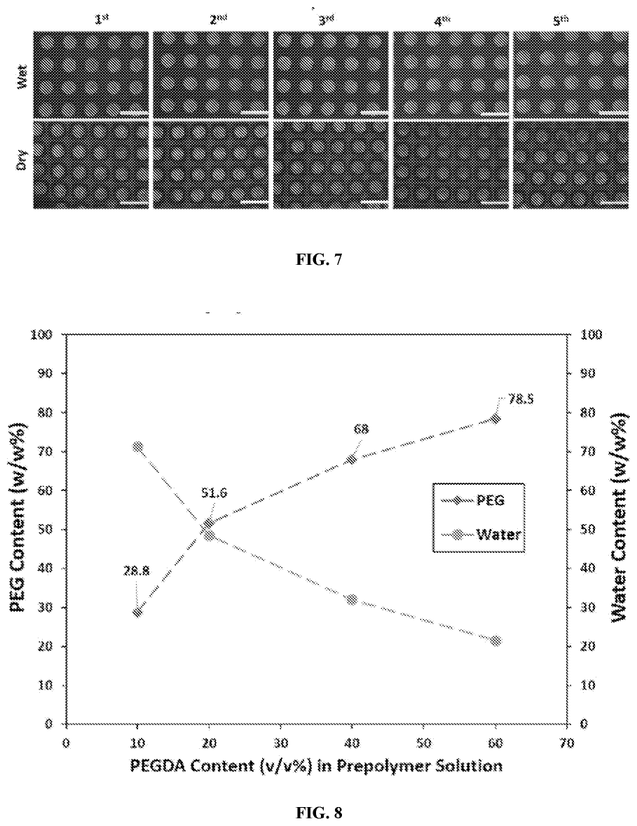

Stimuli Based Response Studies—Drying and Wetting. Films were dehydrated by taking them out of DI water and drying them in open air at room temperature for 30 min. They were then rehydrated in DI water for the same duration. The process was repeated four times for a total of five cycles (FIG. 7).

Stimuli-Based Response Studies—pH Studies. For pH studies, carboxylate-containing films with square-shaped micropatterns were fabricated by photopolymerization of an aqueous prepolymer solution containing 20% HEMA (base polymer), 10% MAA, 10% AA, 7% PEGDA (cross-linker), and 1% PI. To probe the pH response, films were immersed in buffer solutions of different pH values (2.92-7.60). Ionic strength of the buffers was maintained at 240 mM using appropriate amounts of sodium chloride.

Determination of PEG Content. To determine the postpolymerization poly(ethylene) glycol (PEG) content in PEG-based opal hydrogel films, wet mass of the films was determined by weighing them on an analytical balance. The films were then dried to constant mass in an oven at 75° C. for 15 h. PEG content was obtained from the ratios of dry weight to wet weight.

Microscopic Imaging. Dark-field micrographs were obtained using an upright epifluorescence microscope (Olympus BX51, Waltham, MA).

Reflectance Spectrometry. Ultraviolet-visible (UV-vis) reflectance spectra were recorded using a fiber-optic spectrometer (USB-2000, Ocean Optics, Dunedin, FL) with the distance between the sample and fiber tip fixed at 1 mm. An aluminum mirror was used to measure the reference signal of 100% reflectance.

Scanning Electron Microscopy. To obtain the SEM images, films were dried at room temperature for 3 h and sputter-coated with a gold-palladium alloy for 30 s at 30 mA under an argon atmosphere using a Cressington sputter coater 108 (Cressington Scientific Instruments, Watford, UK). The films were then imaged using a Phenom G2 pure scanning electron microscope (Phenom-World BV, Eindhoven, The Netherlands) at 5 kV. ImageJ software was used to analyze the micropatterns in the SEM images.

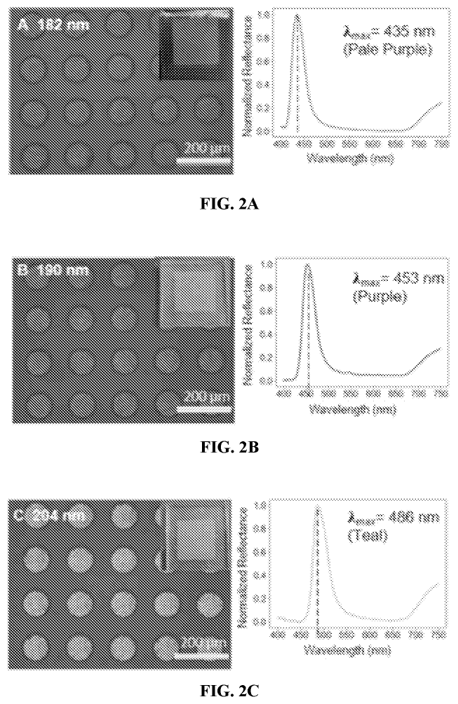

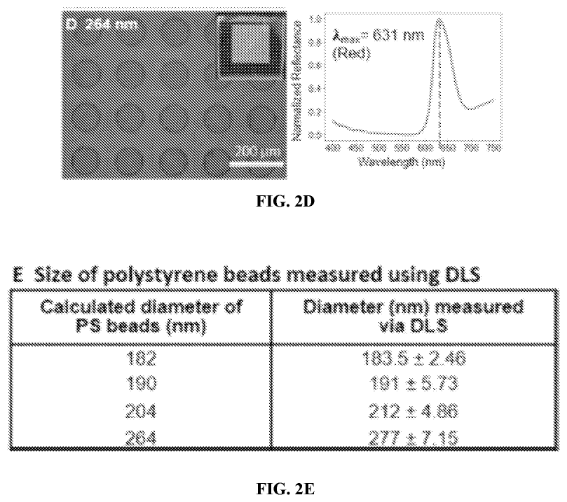

Determination of PS Bead Sizes—Theoretical Estimation. The Bragg equation (eq 1), which describes the relationship between the wavelength of diffracted light (λmax, measured by spectrometry, FIGS. 2A-2D) and the diffracting plane spacing (D) (4 ,27, 33-35) was used to estimate PS bead diameters (sizes). This form of the Bragg equation applies to a system with a close-packed FCC structure in which PS beads are assumed to behave like hard spheres and where incident light is normal to the sample.

$${λ}_{max} - {( \frac{8}{3} )}^{1 / 2} {D ( {n}_{ps}^{2} ϕ + {n}_{void}^{2} ( 1 - ϕ ) )}^{1 / 2} \qquad ( 1 )$$

where λₘₐₓ is the wavelength of diffracted color, D is the diffracting plane spacing (assumed to be equal to the PS bead size), nₚₛ is the refractive index of PS (1.59), ϕ is the PS bead volume fraction (0.74 for FCC) and nvoid is the refractive index of the material in the interstices (air, nair=1.00) (34, 36, 37, 38).

Dynamic Light Scattering. DLS measurements were carried out using a ZetaPALS particle analyzer (Brookhaven, NY) equipped with a 10 mW He—Ne laser at 630 nm wavelength and a temperature of approximately 20° C. Measured PS bead diameters via intensity average are reported from at least three measurements.

### Example 1

### Generation of Highly Uniform Opal Micropatterns by Evaporative Deposition

As shown in FIGS. 2A-2E, it was demonstrated that a simple evaporative deposition of PS beads can be enlisted to generate micropatterns containing artificial opal structures in a controlled and robust manner. Small volumes of aqueous solution containing PS beads with varying sizes were added onto patterned PDMS molds and left the molds in a humidity-controlled chamber (relative humidity >90%) to dry. The molds were then imaged with dark-field optical microscopy, and the spectra of the resulting opals were collected using UV-vis reflectance spectroscopy.

The micrograph and the inset photograph of FIG. 2A show that the PS182 beads (182 nm bead size as determined by the Bragg equation and confirmed by DLS; further discussed below) exhibit faint purple color when deposited into circle-shaped micropatterns, illustrating the formation of “artificial opal” structures via assembly into FCC lattices by hexagonal packing. Similarly, FIGS. 2B-2D shows that PS190, PS204, and PS264 beads deposit into intense purple, teal, and red colors, respectively. All bead types yield highly uniform and intense colors within each micropattern and among micropatterns, illustrating the robust and reliable nature of our simple evaporative deposition method. Several studies have shown promising results for deposition of nanobeads in microwell arrays using evaporative deposition (19, 39-41). Note that in our method here all four bead types are assembled into opals within 30 min, indicating the more rapid nature of this method compared to other deposition techniques (26, 38)

Furthermore, the micrographs in FIGS. 2A-2E show that the opals are formed in highly regular microarrays of circular shapes, arising from the microwells that constitute the micropattern of the PDMS mold. Thus, this method eliminates the need for complex and expensive micropatterning techniques or equipment, illustrating the simple nature of our method.

Next, the UV-vis reflectance spectrum of the opal made with PS182 shows a prominent peak at a wavelength of 435 nm, correlating well with the color in the micrograph and the photograph shown in FIG. 2A. Similar observations are apparent for PS190 (peak at 453 nm), PS204 (peak at 486 nm), and PS264 (peak at 631 nm) whose peaks also coincide with the colors seen in the micrographs and photographs shown in FIGS. 2B-2D, respectively. These sharp and prominent reflectance peaks indicate that our simple evaporation method enables reliable and uniform deposition into micropatterned opal arrays yielding brilliant and intense colors.

The PS bead sizes were first estimated from the UV-reflectance spectra shown in FIGS. 2A-2D via the Bragg equation (eq 1). We then utilized DLS to confirm these estimated PS bead sizes. As reported in the table of FIG. 2E, the diameters of the four types of PS beads measured via DLS show good agreement with those estimated from the Bragg equation (eq 1) using the UV-vis reflectance spectra. Note that the average differences in diameters across the two routes are less than 6%, with the DLS-based values being consistently higher. The observed DLS values are likely to be slightly overestimated because of the negative charge on the PS bead surfaces leading to the formation of a hydration shell under the aqueous colloidal solution condition, thus slightly increasing the observed diameters of the beads (42-43). These results show the reliability of the Bragg equation in predicting sizes of PS beads upon deposition into opal structures. We thus use PS bead sizes determined from Eq. 1 throughout this report. In short summary, the results in FIG. 2A-2E indicate reliable generation of uniform opal structured micropatterns via a simple evaporative deposition method.

### Example 2

### Fabrication of Micropatterned Opal Hydrogel Films via Photoinduced Polymerization

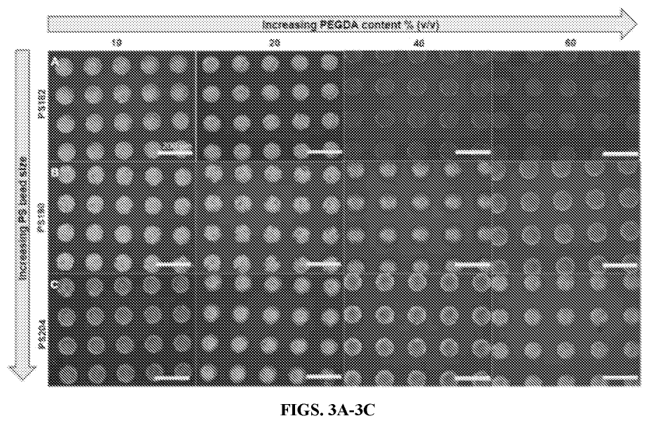

Next, it was demonstrated that hydrogel films containing micropatterned opal structures can be fabricated via simple photoinduced polymerization as shown in FIGS. 3A-3C. Aqueous polymerizable solutions containing varying concentrations of PEGDA and PI (prepolymer solution) were added onto the opal micropatterns and exposed to UV light (365 nm) using a simple handheld lamp upon covering them with coverslips as shown in the schematic diagram of FIG. 1A. The as-formed films were then peeled off from the molds (photograph in FIG. 1C) and imaged in DI water via dark-field optical microscopy.

The micrographs in FIGS. 3A-3C show 12 different films prepared with varying PEGDA content and PS beads of different sizes. First, the micrographs of the top row (FIG. 3A) show that the opal micropatterns of films prepared with PS182 exhibit green to purple colors (left to right) depending on the PEGDA content in the prepolymer solution. From left to right, the 10% film micropatterns display green color, the 20% a green color with a hint of blue, the 40% a bluish-purple, and the 60% a purple color, illustrating the high tunability of opal color by simply changing the PEGDA content.

Importantly, all four conditions examined show that the micropatterns were well preserved upon film formation via polymerization and that the colors remained uniform among and within all the patterns. This uniformity illustrates the robustness and versatility as well as ready tunability of our simple evaporation-polymerization method.

Likewise, the micrographs in the middle row (FIG. 3B) show that the micropatterns of the films prepared with PS190 display colors ranging from green to blue, depending on the PEGDA content in the prepolymer solution. Specifically, the 10% film micropatterns exhibit a green-yellow color, the 20% green, the 40% a bluish-green, and the 60% blue. As with the results from PS182 shown in FIG. 3A, the micropatterns were preserved well, and the colors were highly uniform.

The bottom row (FIG. 3C) shows that the micropatterns of the films of PS204 opals yield orange to green colors. The 10% film shows a red-orange color, the 20% greenish-yellow, the 40% light green, and the 60% green. Again, the micropatterns were well incorporated into the film, and the colors were highly uniform, further supporting the results with PS182 and PS190.

Overall, the results in FIGS. 3A-3C show that the opal structured micropatterns (FIGS. 2A-2D) can be readily captured into hydrogel films with high fidelity and minimal disruption of the crystalline structures via simple photoinduced polymerization. The colors are readily tunable by simple variation of PEGDA content in the prepolymer solution and the PS bead size. Compared to colors of the opals in FIGS. 2A-2D (air-PS system), colors generated by the same bead types in FIGS. 3A-C (wet PEGPS system) are red-shifted under all conditions examined. This is likely a result of both the increase in the refractive index of the interstitial material as wet PEG (1.33<n<1.47) (10, 14) occupies the voids previously filled with air (n=1) and the increase in diffracting plane spacing arising from the swelling of the PEG hydrogel in DI water. According to Bragg's Law (eq 1), both the refractive index and plane spacing correlate positively with the wavelength, implying a red shift in the observed color with a larger refractive index of the interstitial material as with greater plane spacing.

Furthermore, for the same bead type, the colors of micropatterns shown in FIGS. 3A-C vary with the PEGDA content in the prepolymer solution. Specifically, increasing PEGDA content causes blue-shifting, while decreasing PEGDA content results in red-shifting. This is attributed to the varying extents of swelling of PEG hydrogels caused by differing degrees of cross-linking at different PEGDA contents. Low PEG content films arising from low PEGDA prepolymer solutions swell more than the high PEG content films synthesized from high PEGDA prepolymer solutions possibly because of lower polymerization efficiency in the former (44, 45), thus a lower degree of cross-linking. Dense cross-linking of PEG is reported to result in reduced mesh sizes (46, 47) leaving less room for imbibition of water to induce swelling, while lighter cross-linking yields larger mesh sizes that facilitate better water uptake by the hydrogel leading to larger swelling capacity. Consequently, greater swelling leads to larger diffracting plane spacings (proportional to D in eq 1, Theoretical Estimation), thus to longer wavelengths as predicted by eq 1 because D and λ correlate positively. On the other hand, low swelling leads to smaller values of D, thus to shorter wavelengths. This could explain the red-shifting with decreasing PEGDA content and the blue-shifting with increasing PEGDA content.

Note that as the water carrying capacity of the hydrogel changes with the degree of cross-linking, so does the refractive index of the wet hydrogel. However, the refractive index varies over a small range of values (1.33<nwet hydrogel<1.47). Thus, the refractive index contrast would not likely have a significant impact on the changes in color observed for varying PEGDA composition.

Combined, the results of FIGS. 3A-C show reliable and highly tunable synthesis of opal-containing hydrogel films by our integrated evaporation-polymerization method.

### Example 3

### Morphological Characterization of Micropatterned Opal Hydrogel Films by SEM

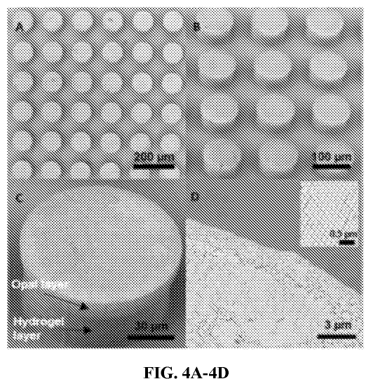

The micropatterned opal hydrogel structures were examined via SEM as shown in FIGS. 4A-D. To acquire these images, opal-containing PEG hydrogel films were synthesized via our evaporation-polymerization method as shown in FIG. 1A, dried, and sputter-coated with a gold-palladium layer, and imaged using SEM.

First, the wide view SEM image of a representative film (PS182, 40% PEGDA) in FIG. 4A shows consistent circle shaped opal micropatterns, clearly indicating the reliable nature of our evaporation-polymerization method. Specifically, this dried sample showed an average circle size of 101±1 μm and an average distance of 40 μm between the patterns. Outside the view shown here, all the patterns possessed 100% fidelity indicating robustness of our simple micromolding technique. Next, the tilted and slightly zoomed-in view of the patterns in FIG. 4B shows similarly reliable patterns along with two-layered structures. This two-layered structure is more apparent in the higher-resolution view in FIG. 4C, where the top and the bottom layers each have distinct diameters and heights. The top layer is most likely the captured opal structure with the hydrogel filling the interstitial spaces among PS beads, while the bottom layer is the dried hydrogel. Finally, the zoomed-in image and the inset of the top opal layer in FIG. 4D reveal hexagonal packing (thus FCC) of the PS beads. This clearly confirms the regularly ordered packing afforded by the simple evaporation step as well as reliable capture of those structures via polymerization into hydrogels. Both the top and sides of the opal layer show uniform packing of PS beads, again showing the reliable nature of the evaporative deposition method.

In short summary, the SEM results in FIG. 4 confirm the hexagonal packing by evaporation and reliable capture of opal micropatterns into hydrogels consistent with the results in FIGS. 2A-2E and 3A-3C, illustrating the robust nature of our evaporation-polymerization method.

### Example 4

### Reversible and Tunable Response of Micropatterned Opal Hydrogel Films to Water Content

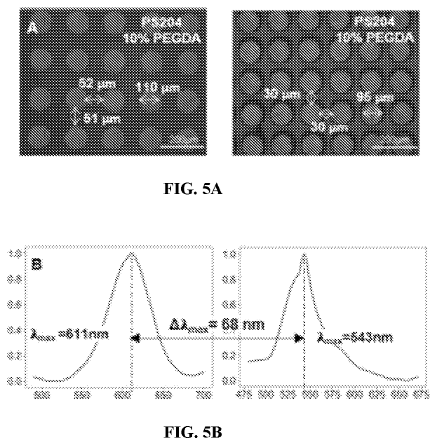

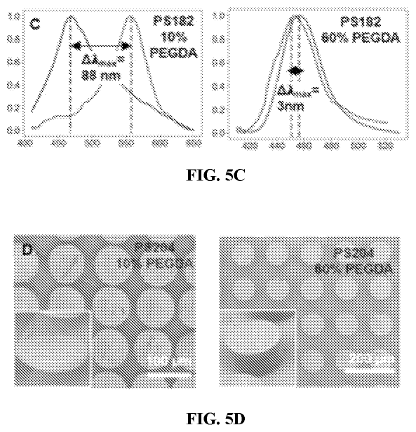

As shown in FIGS. 5A-5D, the responsiveness of the films to changes in water content was examined, illustrating their potential utility toward humidity sensing. For this, the color and UV-vis reflectance spectra of the films were examined in water (wet state) and in open air upon drying at room temperature for 30 min (dried state).

First, the micrographs in FIG. 5A show that the micropatterns of the film fabricated with PS204 and 10% PEGDA display a uniform orange color in wet state, which changes to a uniform green color in the dried state. As indicated in the micrographs, the sizes of the circular micropatterns and the interpattern distances decrease from 110 to 95 μm (13.6% change) and 51 to 30 μm (41.7% change), respectively, upon drying, showing greater shrinkage of the PEG-only parts of the film compared to the opal region containing the more rigid PS beads. The large change in color is also confirmed by UV-vis reflectance spectra in FIG. 5B; peak wavelengths of the wet and the dry states at 611 and 543 nm correspond to the observed orange and green colors, respectively. These results clearly indicate a large shift in color (Δλ=68 nm) for the opal hydrogel films, suggesting potential for simple visual humidity sensing. Meanwhile, repeated drying and wetting for five cycles show complete reversibility of these color changes (FIG. 7), demonstrating the robustness of our opal hydrogel films.

Next in FIG. 5C, the differences in responsiveness to drying between 10 and 60% PEGDA films prepared with PS182 as determined by UV-vis reflectance illustrate the readily tunable nature of our hydrogels. In particular, the 10% PEGDA film showed a large shift in the peak wavelength of 88 nm compared to just 3 nm for the 60% PEGDA film likely because of the more substantial cross-linking and limited swelling of the latter.

Finally, SEM images of films prepared with 10 versus 60% PEGDA in FIG. 5D show morphological differences between these two conditions in thoroughly dried states under SEM's imaging condition in vacuum. The SEM image of the 10% PEGDA film on the left side of FIG. 5D shows circular micropatterns very close to each other, while the zoomed-in inset image shows a narrow stem area indicating substantial shrinkage. In contrast, the right-side SEM image for the 60% PEGDA film shows a thicker stem area and larger interpattern distances, indicating a much smaller degree of shrinkage and higher PEG content.

The results in FIGS. 5A-D present several important features of our integrated deposition-polymerization approach as well as the as-prepared opal hydrogel films. The large shift in color in dry versus wet states indicates high responsiveness and reversibility, while the uniform color throughout each pattern and among patterns shows robustness of the hydrogels that capture and retain the ordered assembly structure of PS beads through extreme changes. This responsiveness is readily tunable via modulation of simple parameters, such as PS bead size and PEGDA content. The color changes accompanying drying or wetting of the opal hydrogel in FIGS. 5A-5D are primarily the result of changes in the diffracting plane spacing. In brief, loss of water during drying causes shrinkage of the hydrogel, leading to reduction in the diffracting plane spacing and hence the blue shift in color from orange to green in FIG. 5A. Reversing the process by re-soaking the hydrogel in DI water leads to swelling of hydrogel, restoration of wet-state diffracting plane spacing, thus the redshift in opal color back to orange (FIG. 7).

Meanwhile, the differences in responsiveness for the 10% versus 60% PEGDA film in FIG. 5C can be attributed to their varying degrees of PEG cross-linking. Compared to the 10% film, the 60% film is more densely cross-linked, with smaller mesh sizes and therefore much lower water uptake capacity. Importantly, we determined that the 10% film contained mostly water (−29% (w/w) PEG, 71% (w/w) water) while the 60% film contained mostly PEG (−78.5% PEG, 21.5% water) (FIG. 8), suggesting propensity for greater shrinkage and swelling of the 10% PEGDA film following water loss and gain respectively, compared to the 60% PEGDA film.

The SEM images of the dried 10% film and the 60% film (FIG. 5D) further support these observations. In particular, the small interpattern distances and the thin stem area beneath the circular opal micropattern of the 10% PEGDA film indicate a low PEG content and substantial shrinkage. On the other hand, the larger distances among micropatterns and the thicker stem area beneath the individual micropatterns of the 60% PEGDA film suggest a high PEG content and limited shrinkage.

In sum, the micrographs, UV-vis reflectance spectra, and SEM results demonstrate substantial and reversible shift in color, robust and tunable nature, and stimuli-responsive properties of our opal hydrogel films.

### Example 5

### Responsiveness of Opal Hydrogel Films to pH

Finally, micropatterned opal hydrogel films were prepared that are responsive to chemical changes, indicating their applicability to environmental sensing. For this, an opal film using PS204 and a prepolymer solution containing HEMA as the base monomer, AA and MAA as carboxylate functional moieties, PEGDA as the cross-linker, and PI, was prepared. Two functional moieties were used because they gave more vivid color changes than AA alone. The resulting poly(HEMAco-AA-co-MAA) film was then immersed in solutions of varying pH (constant ionic strength, I=240 mM), and dark-field optical micrographs were taken for each pH condition upon color equilibration for 20 min (color changes occurred within seconds).

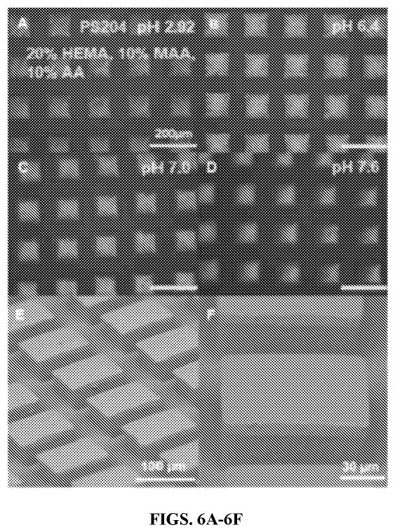

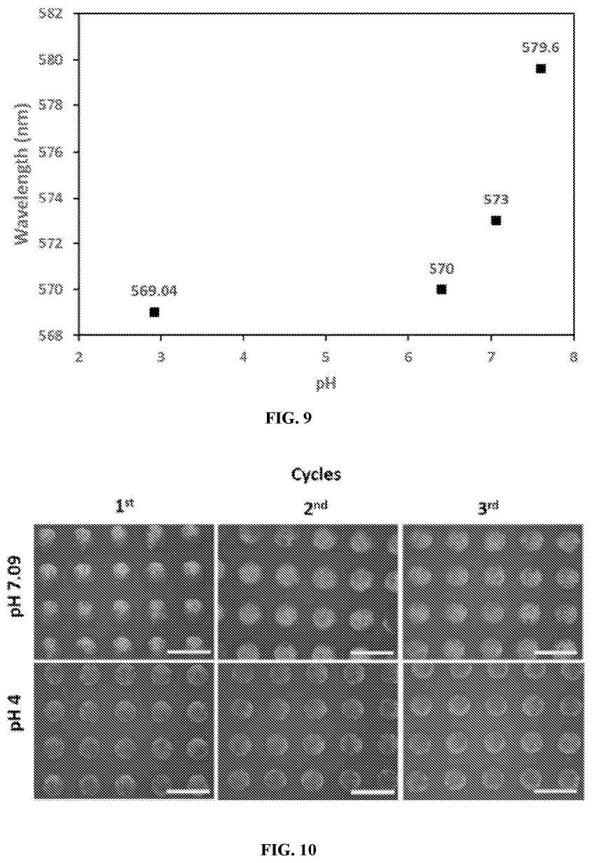

FIGS. 6A-6D shows the film in four solutions of different pH and the same ionic strength. FIG. 6A shows the film in acetate buffer at pH 2.92, while FIGS. 6B-6D shows the same film in phosphate buffers of pH 6.4, 7.0, and 7.6, respectively. The color of the micropatterns changes from green to lime-green to yellow-green to orange, in buffers of pH 2.92, 6.4, 7.0, and 7.6, respectively, illustrating that the opal hydrogel films containing carboxylate functionalities exhibit responsiveness to pH with substantial changes in color. A simple image analysis of the color intensity of the center parts of the patterns shown in FIGS. 6A-6D, shows in FIG. 9 the peak wavelength change from 569 to 580 nm, respectively. This responsiveness is reversible, as further illustrated by the shift in color via three repeated cycles of exposure to varying pH values (FIG. 10), further supporting the robustness of our method and the as-prepared opal hydrogel films.

Meanwhile, FIGS. 6E-6F shows the morphology of the square-shaped micropatterns via SEM. Similar to the circleshaped micropatterns in FIG. 4C, the squareshaped patterns in FIG. 5D show high fidelity with our simple micromolding-based patterning as well as a smaller cross-sectional area at the stem than at the PS bead-containing top layer, indicating robustness of our approach along with greater shrinkage in the hydrogel-only part than in the top in this dried SEM sample.

As with the PEG system previously discussed, the poly(HEMA-co-AA-co-MAA) system with square-shaped micropatterns yields films with highly uniform colors, indicating the versatility of our synthesis technique with different polymer systems as well as various simple 2D shapes. Note, AA as the only co-monomer tends to produce brittle hydrogels that do not exhibit robust mechanical integrity as partially observed in one of our recent studies (31) as well as in other reports (48,49).

The poly(HEMA-co-AA-co-MAA) films had an experimentally determined pKa value of 5.08, which is slightly higher than the individual pKa values of poly(acrylic acid) (pKa 4.5) and poly(methacrylic acid) (pKa 4.8) (50-51). For pH values below the pKa of the hydrogel, green color was observed, while a gradual redshift in color was seen for pH values above the pKa (FIGS. 6A-6D). These results are expected because the carboxyl groups exist in their neutral, protonated state under low-pH (<pKa) conditions and exhibit minimal swelling. They ionize converting into anionic carboxylate groups under highpH (>pKa) conditions. This ionization leads to red-shifting by potentially inducing two factors, which contribute to swelling of the hydrogels: the increase in Donnan osmotic potential and the repulsive anion—anion charge interactions. First as pH increases beyond pKa, formation of fixed carboxylate anions increases the negative charge within the hydrogel film. This in turn induces an influx of cations from the buffer solution to counter the growing negative charge to maintain neutrality.

With an imbalance of cations between the buffer and the hydrogel, Donnan potential of the hydrogel increases leading to entry of water into the gel and the subsequent increase in gel volume. Second, the repulsive interactions between the created anions cause extension of the polymer chains, increasing the volume of the gels. The swelling induced by these two factors leads to an increase in the diffracting plane spacing and consequently, the Bragg diffraction wavelength.

In short summary, the results described herein show that process can be used to synthesize stimuli-responsive materials.

### DISCUSSION

The present invention demonstrates a simple, rapid, and inexpensive evaporation-polymerization technique based on micromolding and its potential application in sensing. First, highly uniform artificial opal structures were generated in micropatterned molds via simple evaporative deposition in a rapid, controlled, and robust manner. Next, the as-prepared opal structures were incorporated into PEG-based hydrogels to produce micropatterned hydrogel films via simple photoinduced polymerization with highly uniform colors that can be tuned simply by changing the PEGDA content in the prepolymer solution. The opal hydrogel films are highly responsive to change in water content and pH with a reversible and large shift up to 88 nm observed.

Overall, the disclosed evaporation-deposition technique provides a platform for manufacturing highly tunable and responsive micropatterned opal hydrogel film materials suitable for a wide range of sensing applications.

### REFERENCES CITED

(1) Sanders, J. Colour of Precious Opal. Nature 1964, 204, 1151-1153.
(2) Arsenault, A. C.; Puzzo, D. P.; Manners, I.; Ozin, G. A. Photonic-Crystal Full-Colour Displays. Nat. Photonics 2007, 1, 468-472.
(3) Fudouzi, H.; Xia, Y. Colloidal Crystals with Tunable Colors and Their Use as Photonic Papers. Langmuir 2003, 19, 9653-9660.
(4) Mayoral, R.; Requena, J.; Moya, J. S.; Lopez, C.; Cintas, A.; Miguez, H.; Meseguer, F.; Vázquez, L.; Holgado, M.; Blanco, Á. 3D Long-Range Ordering in an SiO₂ Submicrometer-Sphere Sintered Superstructure. Adv. Mater. 1997, 9, 257-260.
(5) Bazin, G.; Zhu, X. Crystalline Colloidal Arrays from the Self-Assembly of Polymer Microspheres. Prog. Polym. Sci. 2013, 38, 406-419.
(6) Lee, K.; Asher, S. A. Photonic Crystal Chemical Sensors: pH and Ionic Strength. J. Am. Chem. Soc. 2000, 122, 9534-9537.
(7) Lee, Y. J.; Braun, P. V. Tunable Inverse Opal Hydrogel pH Sensors. Adv. Mater. 2003, 15, 563-566.
(8) Tian, E.; Wang, J.; Zheng, Y.; Song, Y.; Jiang, L.; Zhu, D. Colorful Humidity Sensitive Photonic Crystal Hydrogel. J. Mater. Chem. 2008, 18, 1116-1122.
(9) Xing, H.; Li, J.; Guo, J.; Wei, J. Bio-Inspired Thermal-Responsive Inverse Opal Films with Dual Structural Colors Based on Liquid Crystal Elastomer. J. Mater. Chem. C 2015, 3, 4424-4430.
(10) Xu, X.; Goponenko, A. V.; Asher, S. A. Polymerized Polyhema Photonic Crystals: pH and Ethanol Sensor Materials. J. Am. Chem. Soc. 2008, 130, 3113-3119.
(11) Hou, J.; Li, M.; Song, Y. Patterned Colloidal Photonic Crystals. Angew. Chem., Int. Ed. 2018, 57, 2544-2553.
(12) Quist, A. P.; Oscarsson, S. Micropatterned Surfaces: Techniques and Applications in Cell Biology. Expert Opin. Drug Discovery 2010, 5, 569-581.
(13) Lee, Y.; Park, S.; Han, S. W.; Lim, T. G.; Koh, W. G. Preparation of Photolithographically Patterned Inverse Opal Hydrogel Microstructures and Its Application to Protein Patterning. Biosens. Bioelectron. 2012, 35, 243-250.
(14) Pei, Y.; Molley, T. G.; Kilian, K. A. Enzyme Responsive Inverse Opal Hydrogels. Macromol. Rapid Commun. 2020, 41, No. 1900555.
(15) Yu, B.; Cong, H.; Yang, Z.; Yang, S.; Wang, Y.; Zhai, F.; Wang, Y. Preparation of Humidity-Sensitive Poly (Ethylene Glycol) Inverse Opal Micropatterns Using Colloidal Lithography. Materials 2017, 10, 1035.
(16) Kim, H.; Ge, J.; Kim, J.; Choi, S.; Lee, H.; Lee, H.; Park, W.; Yin, Y.; Kwon, S. Structural Colour Printing Using a Magnetically Tunable and Lithographically Fixable Photonic Crystal. Nat. Photonics 2009, 3, 534-540.
(17) Lee, S. Y.; Kim, S. H.; Hwang, H.; Sim, J. Y.; Yang, S. M. Controlled Pixelation of Inverse Opaline Structures Towards Reflection-Mode Displays. Adv. Mater. 2014, 26, 2391-2397.
(18) Lee, S. Y.; Kim, S. H.; Heo, C. J.; Hwang, H.; Yang, S. M. Lithographically-Featured Photonic Microparticles of Colloidal Assemblies. Phys. Chem. Chem. Phys. 2010, 12, 11861-11868.
(19) Maeda, Y.; Yoshida, R. Fabrication of Micropatterned Thermosensitive Gel with Highly-Ordered Honeycomb Surface and Inverse Opal Structure. Biomed. Microdevices 2009, 11, 809-815.
(20) Singh, A.; Kulkarni, S. K.; Khan Malek, C. Patterning of SiO₂ Nanoparticle—Pmma Polymer Composite Microstructures Based on Soft Lithographic Techniques. Microelectron. Eng. 2011, 88, 939-944.
(21) Yao, J.; Yan, X.; Lu, G.; Zhang, K.; Chen, X.; Jiang, L.; Yang, B. Patterning Colloidal Crystals by Lift-up Soft Lithography. Adv. Mater. 2004, 16, 81-84.
(22) Ding, T.; Zhao, Q.; Smoukov, S. K.; Baumberg, J. J. Selectively Patterning Polymer Opal Films Via Microimprint Lithography. Adv. Opt. Mater. 2014, 2, 1098-1104.
(23) Yang, J. C.; Hong, S. W.; Park, J. Molecular Imprinting of Polymer Films on 2D Silica Inverse Opal Via Thermal Graft Copolymerization for Bisphenol a Detection. Sens. Actuators, B 2020, 323, No. 128670.
(24) Yan, Q.; Nukala, P.; Chiang, Y.-M.; Wong, C. Three-Dimensional Metallic Opals Fabricated by Double Templating. Thin Solid Films 2009, 517, 5166-5171.
(25) Jiang, P.; McFarland, M. J. Large-Scale Fabrication of Wafer-Size Colloidal Crystals, Macroporous Polymers and Nanocomposites by Spin-Coating. J. Am. Chem. Soc. 2004, 126, 13778-13786.
(26) Kim, J. B.; Lee, G. H.; Kim, S. H. Interfacial Assembly of Amphiphilic Tiles for Reconfigurable Photonic Surfaces. ACS Appl. Mater. Interfaces 2019, 11, 45237-45245.
(27) Kim, S. H.; Lee, S. Y.; Yang, S. M.; Yi, G. R. Self-Assembled Colloidal Structures for Photonics. NPG Asia Mater. 2011, 3, 25-33.
(28) Lee, H.; Jeon, T. Y.; Lee, S. Y.; Lee, S. Y.; Kim, S. H. Designing Multicolor Micropatterns of Inverse Opals with Photonic Bandgap and Surface Plasmon Resonance. Adv. Funct. Mater. 2018, 28, No. 1706664.
(29) Xu, J.; Guo, Z. Biomimetic Photonic Materials with Tunable Structural Colors. J. Colloid Interface Sci. 2013, 406, 1-17.
(30) Fu, X.; Cai, J.; Zhang, X.; Li, W. D.; Ge, H.; Hu, Y. Top-Down Fabrication of Shape-Controlled, Monodisperse Nanoparticles for Biomedical Applications. Adv. Drug Delivery Rev. 2018, 132, 169-187.
(31) Liu, E. Y.; Jung, S.; Yi, H. Improved Protein Conjugation with Uniform, Macroporous Poly (Acrylamide-co-Acrylic Acid) Hydrogel Microspheres Via EDC/NHS Chemistry. Langmuir 2016, 32, 11043-11054.
(32) Du, X.; He, J. Facile Size-Controllable Syntheses of Highly Monodisperse Polystyrene Nano-and Microspheres by Polyvinylpyrrolidone-Mediated Emulsifier-Free Emulsion Polymerization. J. Appl. Polym. Sci. 2008, 108, 1755-1760.
(33) Armstrong, E.; O'Dwyer, C. Artificial Opal Photonic Crystals and Inverse Opal Structures—Fundamentals and Applications from Optics to Energy Storage. J. Mater. Chem. C 2015, 3, 6109-6143.
(34) Ozin, G. A.; Arsenault, A. C. P-Ink and Elast-Ink from Lab to Market. Mater. Today 2008, 11, 44-51.
(35) Shim, T. S.; Kim, S. H.; Sim, J. Y.; Lim, J. M.; Yang, S. M. Dynamic Modulation of Photonic Bandgaps in Crystalline Colloidal Arrays under Electric Field. Adv. Mater. 2010, 22, 4494-4498.
(36) Gaulding, E.; Liu, G.; Chen, C.; Löbbert, L.; Li, A.; Segev, G.; Eichhorn, J.; Aloni, S.; Schwartzberg, A.; Sharp, I. Fabrication and Optical Characterization of Polystyrene Opal Templates for the Synthesis of Scalable, Nanoporous (Photo) Electrocatalytic Materials by Electrodeposition. J. Mater. Chem. A 2017, 5, 11601-11614.
(37) Hu, Z.; Lu, X.; Gao, J. Hydrogel Opals. Adv. Mater. 2001, 13,1708-1712.
(38) Gu, Z. Z.; Fujishima, A.; Sato, O. Fabrication of High-Quality Opal Films with Controllable Thickness. Chem. Mater. 2002, 14,760-765.
(39) Kim, J. B.; Lee, S. Y.; Lee, J. M.; Kim, S. H. Designing Structural-Color Patterns Composed of Colloidal Arrays. ACS Appl. Mater. Interfaces 2019, 11, 14485-14509.
(40) Lee, G. H.; Jeon, T. Y.; Kim, J. B.; Lee, B.; Lee, C. S.; Lee, S. Y.; Kim, S. H. Multicompartment Photonic Microcylinders toward Structural Color Inks. Chem. Mater. 2018, 30, 3789-3797.
(41) Park, J.; Moon, J.; Shin, H.; Wang, D.; Park, M. Direct-Write Fabrication of Colloidal Photonic Crystal Microarrays by Ink-Jet Printing. J. Colloid Interface Sci. 2006, 298, 713-719.
(42) Fenzl, C.; Wilhelm, S.; Hirsch, T.; Wolfbeis, 0. S. Optical Sensing of the Ionic Strength Using Photonic Crystals in a Hydrogel Matrix. ACS Appl. Mater. Interfaces 2013, 5, 173-178.
(43) Venditti, I.; Fratoddi, I.; Palazzesi, C.; Prosposito, P.; Casalboni, M.; Cametti, C.; Battocchio, C.; Polzonetti, G.; Russo, M. V. Self-Assembled Nanoparticles of Functional Copolymers for Photonic Applications. J. Colloid Interface Sci. 2010, 348, 424-430.
(44) Andrzejewska, E. Photopolymerization Kinetics of Multifunctional Monomers. Prog. Polym. Sci. 2001, 26, 605-665.
(45) Panda, P.; Ali, S.; Lo, E.; Chung, B. G.; Hatton, T. A.; Khademhosseini, A.; Doyle, P. S. Stop-Flow Lithography to Generate Cell-Laden Microgel Particles. Lab Chip 2008, 8, 1056-1061.
(46) Rehmann, M. S.; Skeens, K. M.; Kharkar, P. M.; Ford, E. M.; Maverakis, E.; Lee, K. H.; Kloxin, A. M. Tuning and Predicting Mesh Size and Protein Release from Step Growth Hydrogels. Biomacromolecules 2017, 18, 3131-3142.
(47) Toepke, M. W.; Impellitteri, N. A.; Theisen, J. M.; Murphy, W. L. Characterization of Thiol-Ene Crosslinked PEG Hydrogels. Macromol. Mater. Eng. 2013, 298, 699-703.
(48) Khare, A. R.; Peppas, N. A. Swelling/Deswelling of Anionic Copolymer Gels. Biomaterials 1995, 16, 559-567.
(49) Shen, J.; Yan, B.; Li, T.; Long, Y.; Li, N.; Ye, M. Mechanical, Thermal and Swelling Properties of Poly (Acrylic Acid)—Graphene Oxide Composite Hydrogels. Soft Matter 2012, 8, 1831-1836.
(50) Liu, L.; Luo, S. Z.; Wang, B.; Guo, Z. H. Investigation of Small Molecular Weight Poly (Acrylic Acid) Adsorption on γ-Alumina. Appl. Surf. Sci. 2015, 345, 116-121.
(51) Huang, X.; Mutlu, H.; Theato, P. A Bioinspired Hierarchical Underwater Superoleophobic Surface with Reversible pH Response. Adv. Mater. Interfaces 2020, 7, No. 2000101.

### INCORPORATION BY REFERENCE

All of the U.S. patents and U.S. and PCT published patent applications cited herein are hereby incorporated by reference.

### EQUIVALENTS

The foregoing written specification is considered to be sufficient to enable one skilled in the art to practice the invention. The present invention is not to be limited in scope by examples provided, since the examples are intended as a single illustration of one aspect of the invention and other functionally equivalent embodiments are within the scope of the invention. Various modifications of the invention in addition to those shown and described herein will become apparent to those skilled in the art from the foregoing description and fall within the scope of the appended claims. The advantages and objects of the invention are not necessarily encompassed by each embodiment of the invention.

What is claimed is:

1. A method for producing a micropatterned opal hydrogel film, comprising:
(i) depositing a suspension of nanoparticles in at least one solvent into a plurality of poly(dimethyl siloxane) (PDMS) microwells;
(ii) subjecting the suspension, for a first period of time, to conditions sufficient to evaporate the at least one solvent;
(iii) adding a solution comprising a monomer or a co-monomer to the plurality of PDMS microwells; and
(iv) subjecting the solution, for a second period of time to conditions sufficient to polymerize the monomer or co-monomer, thereby producing the micropatterned opal hydrogel film.

2. The method of claim 1, wherein the plurality of PDMS microwells are circle shaped.

3. The method of claim 2, wherein the micropatterned opal hydrogel film is characterized by a plurality of circle shaped surface features.

4. The method of claim 3, wherein each circle shaped surface feature has a uniform diameter ±5 μm.

5. The method of claim 2 or 3, wherein each circle shaped surface feature is spaced apart by a uniform distance ±2 μm.

6. The method of claim 1, wherein the plurality of PDMS microwells are square shaped.

7. The method of claim 7, wherein the micropatterned opal hydrogel film is characterized by a plurality of square shaped surface features.

8. The method of claim 7, wherein each square shaped surface feature has a uniform width ±5 μm.

9. The method of claim 7 or 8, wherein each square shaped surface feature is spaced apart by a uniform distance ±2 μm.

10. The method of any one of claims 1-9, wherein the nanoparticles are suspended in a mixture comprising water and an organic solvent.

11. The method of claim 10, wherein the nanoparticles are suspended in a 5:5 to 7:3 mixture of water and an organic solvent.

12. The method of claim 11, wherein the nanoparticles are suspended in a 6:4 mixture of water and an organic solvent.

13. The method of claim 10 or 11, wherein the organic solvent is an alcohol.

14. The method of claim 13, wherein the alcohol is ethanol.

15. The method of any one of claims 1-14, wherein the nanoparticles are polystyrene (PS) beads.

16. The method of claim 15, wherein the PS beads have a diameter of about 180-219 nm.

17. The method of claim 15, wherein the PS beads have a diameter of about 260-279 nm.

18. The method of claim 16, wherein the PS beads have a diameter of about 180-189 nm.

19. The method of claim 16, wherein the PS beads have a diameter of about 190-199 nm.

20. The method of claim 16, wherein the PS beads have a diameter of about 200-209 nm.

21. The method of claim 16, wherein the PS beads have a diameter of about 210-219 nm.

22. The method of claim 17, wherein the PS beads have a diameter of about 260-269 nm.

23. The method of claim 17, wherein the PS beads have a diameter of about 270-279 nm.

24. The method of any one of claims 1-14, wherein the nanoparticles are silica nanoparticles.

25. The method of any one of claims 1-24, wherein in step (ii) the suspension is subjected a relative humidity of 80-99%.

26. The method of claim 25, wherein the relative humidity of 85-95%.

27. The method of claim 26, wherein the relative humidity of 88-92%.

28. The method of any one of claims 1-27, wherein the first period of time is about 15 to 45 min.

29. The method of claim 28, wherein the first period of time is about 30 min.

30. The method of any one of claims 1-29, wherein in step (iii) the monomer or co-monomer is about 5-65% v/v in the solution.

31. The method of claim 30, wherein the monomer or co-monomer is about 5-15% v/v in the solution.

32. The method of claim 30, wherein the monomer or co-monomer is about 15-25% v/v in the solution.

33. The method of claim 30, wherein the monomer or co-monomer is about 35-45% v/v in the solution.

34. The method of claim 30, wherein the monomer or co-monomer is about 55-65% v/v in the solution.

35. The method of any one of claims 30-34, wherein the solution is an aqueous solution.

36. The method of any one of claims 1-35, wherein in step (iii) the solution comprises a monomer which is polymerizable by UV radiation.

37. The method of any one of claims 1-35, wherein in step (iii) the solution comprises a co-monomer which is polymerizable by UV radiation.

38. The method of claim 36, wherein the monomer is a polyether acrylate monomer or a methacrylate monomer.

39. The method of claim 38, wherein the monomer is polyethylene glycol diacrylate (PEGDA).

40. The method of claim 38, wherein the monomer is 2-hydroxyethylmethacrylate (HEMA).

41. The method of claim 36, wherein the monomer is poly(ethylene glycol), dimethacrylate, or acrylamide.

42. The method of claim 37, wherein the co-monomer is acrylic acid, methacrylic acid, or bisacrylamide.

43. The method of any one of claims 36-42, wherein in step (iv) the monomer or co-monomer is subjected to UV light to polymerize the monomer or co-monomer.

44. The method of claim 43, wherein the UV light is 365 nm UV light.

45. The method of any one of claims 36-44, wherein the second period of time is about 15 to about 45 min.

46. The method of claim 45, wherein the second period of time is about 30 min.

47. The method of any one of claims 1-35, wherein in step (iii) the solution comprises a monomer which is polymerizable by thermal polymerization.

48. The method of any one of claims 1-35, wherein in step (iii) the solution comprises a co-monomer which is polymerizable by thermal polymerization.

49. The method of claim 47, wherein the monomer is gelatin, agarose, or ionogel

50. The method of claim 48, wherein the co-monomer is gelatin.

51. The method of any one of claims 47-50, wherein the solution is a hot solution.

52. The method of claim 51, wherein in step (iv) the hot solution of the monomer or co-monomer is allowed to cool to room temperature to polymerize the monomer or co-monomer.

53. The method of any one of claims 1-35, wherein in step (iii) the solution comprises a monomer which is polymerizable by exposure to a Ca²⁺.

54. The method of any one of claims 1-35, wherein in step (iii) the solution comprises a co-monomer which is polymerizable by exposure to a Ca²⁺.

55. The method of claim 54, wherein the monomer is alginate.

56. The method of any one of claims 53-55, wherein in step (iv) a solution comprising Ca²⁺ is added to the to the plurality of PDMS microwells to polymerize the monomer or co-monomer.

57. The method of any one of claims 1-35, wherein in step (iii) the solution comprises a monomer which is polymerizable by exposure to a strong base.

58. The method of any one of claims 1-35, wherein in step (iii) the solution comprises a co-monomer which is polymerizable by exposure to strong base.

59. The method of claim 57, wherein the monomer is chitosan.

60. The method of claim 58, wherein the co-monomer is chitosan.

61. The method of any one of claims 57-60, wherein in step (iv) a strongly basic solution is added to the to the plurality of PDMS microwells to polymerize the monomer or co-monomer.

62. The method of any one of claims 1-61, wherein the opal hydrogel film is a two-layered structure.

63. The method of any one of claims 1-61, wherein the micropatterned opal hydrogel film is green.

64. The method of any one of claims 1-61, wherein the micropatterned opal hydrogel film is yellow.

65. The method of any one of claims 1-61, wherein the micropatterned opal hydrogel film is purple.

66. The method of any one of claims 1-61, wherein the micropatterned opal hydrogel film is blue.

67. The method of any one of claims 1-66, wherein the micropatterned opal hydrogel film changes color in response to a change in pH.

68. A micropatterned opal hydrogel film prepared by the method of any one of claims 1-67.

69. A micropatterned opal hydrogel film characterized by a plurality of shaped surface features, wherein each shaped surface features comprises an opal-containing top layer and a hydrogel bottom layer.

70. A micropatterned opal hydrogel film characterized by a plurality of shaped surface features, wherein each shaped surface features consists of an opal-containing top layer and a hydrogel bottom layer.

71. The micropatterned opal hydrogel film of claim 69 or 70, wherein the shaped surface features are circle or square shaped surface features.

72. The micropatterned opal hydrogel film of claim 71, wherein each circle shaped surface feature has a uniform diameter ±5 μm.

73. The micropatterned opal hydrogel film of claim 71 or 72, wherein each circle shaped surface feature is spaced apart by a uniform distance ±2 μm.

74. The micropatterned opal hydrogel film of claim 744, wherein each square shaped surface feature has a uniform width ±5 μm.

75. The micropatterned opal hydrogel film of claim 73 or 74, wherein each square shaped surface feature is spaced apart by a uniform distance ±2 μm.

76. The micropatterned opal hydrogel film of claims 69-75, wherein the opal-containing top layer comprises nanoparticles.

77. The micropatterned opal hydrogel film of claim 76, wherein the nanoparticles are polystyrene or silica nanoparticles.

78. The micropatterned opal hydrogel film of claim 76 or 77, wherein the opal-containing top layer is formed by evaporating a suspension of the nanoparticles in at least one solvent.

79. The micropatterned opal hydrogel film of any one of claims 69-78, wherein the hydrogel bottom layer comprises a polymer.

80. The micropatterned opal hydrogel film of claim 79, wherein the polymer is formed by polymerization of a monomer and/or co-monomer.

81. The micropatterned opal hydrogel film of any one of claims 69-80, wherein the micropatterned opal hydrogel film changes color in response to a change in pH.
